(19) United States
(12) Patent Application Publication
(10) Pub. No.: US 2014/0035079 A1
(43) Pub. Date: Feb. 6, 2014

(54) Window Type Camera Module Structure

(71) Applicant: Shin-Dar Jan, Hsinchu City (TW)

(72) Inventor: Shin-Dar Jan, Hsinchu City (TW)

(73) Assignee: LARVIEW TECHNOLOGIES CORPORATION, Yangmei City (TW)

(21) Appl. No.: 13/565,576

(22) Filed: Aug. 2, 2012

(51) Int. Cl. H01L 31/0232

(52) U.S. Cl. 257/432; 257/E31.127

(57) ABSTRACT

The present invention provides a window type camera module structure comprising a first substrate. A chip is configured on the first substrate, with a first contact pad and a sensing area. A second substrate is disposed on the first substrate, with a through hole structure and a second contact pad, wherein the chip is disposed within the through hole structure. The first contact is coupled to the second contact pad via a wire. A lens holder is disposed on the second substrate, and a lens is located on the top of the lens holder. A transparent material is disposed on the lens holder or the second substrate. The lens is substantially aligning to the transparent material and the sensing area.

### TECHNICAL FIELD

The present invention generally relates to semiconductor device structure, more particularly, to a window type camera module structure by integrating a lens holder and an image sensor to reduce the device size.

### BACKGROUND

In the field of semiconductor devices, the device density is increased and the device dimension is reduced, continuously. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor chip become more complicated, the traditional package technique, for example lead frame package, flex package, rigid package technique, can't meet the demand of producing smaller chip with high density elements on the chip. Wafer level package (WLP) technique is an advanced packaging technology, by which the dice are manufactured and tested on the wafer, and then the wafer is singulated by dicing for assembly in a surface-mount line. Because the wafer level package technique utilizes the whole wafer as one object, not utilizing a single chip or die, and therefore, before performing a scribing process, packaging and testing has been accomplished. Furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Currently, the flip chip technology used for the camera module is performed as a stud bump process on the entire wafer by a wire bonding equipment, whereby solder balls to being replaced by the stud bumps.

A CMOS image sensor is manufactured into a CMOS image sensor module from a CMOS image sensor chip by an electronic package technology. And it is applied into various goods and a package specification required by the CMOS image sensor module depends on characteristics of the finished goods. Especially, the recent tendencies of a CMOS image sensor module, namely, high electricity capabilities, miniaturization/high density, a low power consumption, multifunction, a high speed signal processing, a reliability are the representative characteristics of a miniaturization of the electronic goods.

Contrary to general CMOS chips, the CMOS image sensor in the past is feasible to a physical environment and can be polluted by the impurities, and a leadless chip carrier LCC type package is used when its size is not considered to be important. However, in a recent tendency of a market requiring for thin and simplified characteristics such as in a camera phone, smart phone, chip-on-board (COB), chip-on-film (COF), chip size package (CSP), etc. are generally used.

Current flip chip structure can reduce module height but flip chip machine is very expensive and low UPH (Unit Per Hour). So, the investment is very huge. And, yield is lower and not easy to be controlled.

Therefore, based-on the shortcomings of prior arts, the present invention provide a newly window type camera module structure, which has no need for new investment and the process yield will be better.

### SUMMARY OF THE INVENTION

Based-on the shortcomings of the above-mentioned, an objective of the present invention is to provide a window type camera module structure with a smaller height of the module structure.

Another objective of the present invention is to provide a window type camera module structure by integrating a lens holder and an image sensor and employing the same standard TTL lens design to reduce the device size, and enhancing yield and reliability.

Yet another objective of the present invention is to provide a window type camera module structure with good thermal performance, lower cost and easy to manufacture.

According to an aspect of the present invention, the present invention provides a window type camera module structure. The module structure comprises a first substrate. A chip is configured on the first substrate, with a first contact pad and a sensing area. A second substrate is disposed on the first substrate and the chip, with a through hole structure and a second contact pad, wherein the chip is disposed within the through hole structure. The first contact is coupled to the second contact pad via a wire. A transparent material is disposed on the lens holder or the second substrate. A lens holder is disposed on the second substrate, and a lens is located on the top of the lens holder, substantially aligning to the transparent material and the sensing area.

The lens holder of the module structure includes an upper portion and a lower portion, wherein the lens is disposed on the lower portion and the transparent material is disposed on the upper portion. The second substrate is adhered to the first substrate via a conductive layer for electrically connecting with each other. The first substrate is a printed circuit board or a flexible printed circuit board, with a trace formed thereon, respectively. The chip is adhered to the first substrate via an adhesion layer.

In another example, a top surface of the second substrate includes two regions with different step height, wherein the second contact pad is formed on a top surface of relative low region, and the transparent material is formed on a top surface of relative high region.

In yet another example, the module structure further comprises a passivation layer formed on the first substrate, the chip and the second substrate, wherein the passivation layer is fully-covering, partially-covering or non-covering over the wire.

### BRIEF DESCRIPTION OF THE DRAWINGS

The components, characteristics and advantages of the present invention may be understood by the detailed descriptions of the preferred embodiments outlined in the specification and the drawings attached:

FIG. 1 illustrates a sectional view of a flip chip package structure;

FIG. 2 illustrates a sectional view of a window type camera module structure according to the present invention;

FIG. 3 illustrates a sectional view of a window type camera module structure according to an embodiment of the present invention;

FIG. 4 illustrates a sectional view of a window type camera module structure according to another embodiment of the present invention;

FIG. 5 illustrates a sectional view of a window type camera module structure according to yet another embodiment of the present invention.

FIG. 6 illustrates a sectional view of a window type camera module structure according to an embodiment of the present invention.

FIG. 7 illustrates a sectional view of a window type camera module structure according to another embodiment of the present invention.

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

The present invention provides a window type camera module structure which can be manufactured by employing a chip-on-board (COB) packaging technique. The chip-on-board (COB) packaging technique is used for the integrated circuit packaging, which the chip is adhered on the circuit board or substrate, and thereby effectively performing chip packaging and testing based-on the circuit board assembly.

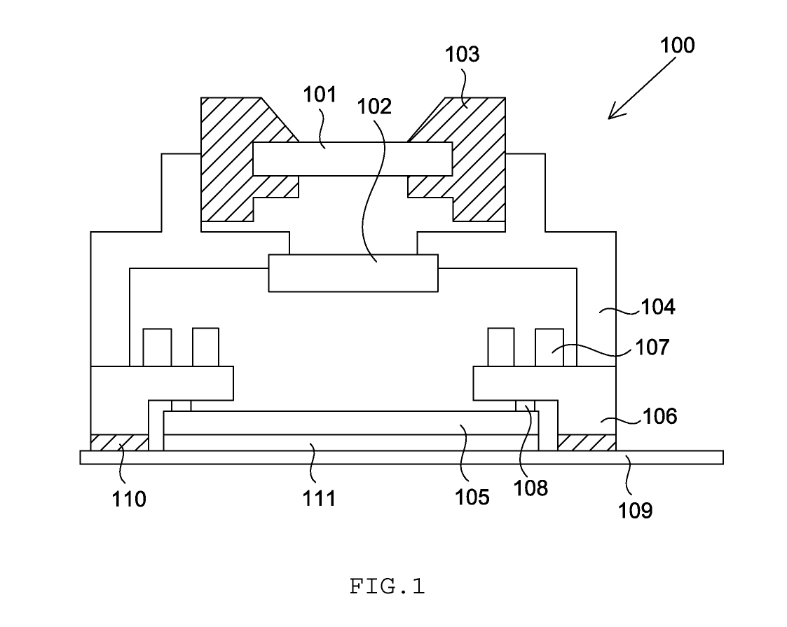

FIG. 1 shows a sectional view of a flip chip package structure. As shown in FIG. 1, the flip chip package structure 100 comprises a substrate 106, a chip 105, a passive component 107, a lens holder 104, a lens 101 and a transparent plate (material) 102. The substrate 106 has a concave structure formed therein for receiving the chip 105 and a conductive layer 108. The chip 105 and the conductive layer 108 are formed under the substrate 106, wherein the conductive layer 108 is electrically connected to the substrate 106 and a contact pad of the chip 105. The lens holder 104 includes a jig 103 for fixing the lens 101. At least one passive component 107 is formed (adhered) on the substrate 106 within the lens holder 104. The lens 101 is disposed on the upper portion of the lens holder 104. Moreover, the transparent plate 102 is optionally disposed within the lens holder 104, between the lens 101 and the chip 105. The lens holder 104 is adhered to the substrate 106 via an adhesion layer. Moreover, the flip chip package structure 100 further comprises a printed circuit board 109 with a conductive wire configured at the extension area outside the substrate 106, for electrically connecting to other components. The substrate 106 is adhered to the printed circuit board 109 via the conductive layer 110 for electrically connecting to each other. The heat dissipation layer 111 is formed between the chip 105 and the printed circuit board 109 for facilitating heat dissipation.

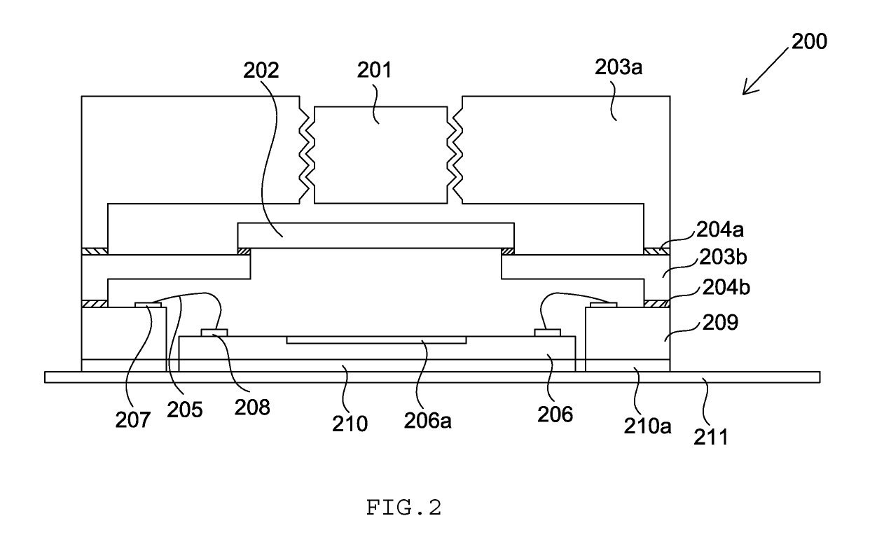

FIG. 2 shows a sectional view of a window type camera module structure by integrating a lens holder and an image sensor chip according to the present invention. As shown in FIG. 2, the window type camera module structure 200 integrates the lens holder and the image sensor chip to be as a module structure with sensing function, which can be applied to a camera module of a mobile phone or other portable devices. The window type camera module structure 200 comprises a substrate 209 and a substrate 211, a chip 206, an upper portion/lower portion of a lens holder 203a/203b, a lens 201 and a transparent plate (material) 202.

The top surface of the chip 206 is exposed to the through hole structure completely, and the sensing area 206a and the contact pad (I/O pad) 208 are exposed to the window area. In an example, the chip 206 may be electrically to a conductive layer on the substrate 211. For example, the chip 206 is an image sensor chip which has a sensing area 206a on its surface and a contact pad 208 formed thereon. The substrate 211 is a printed circuit board or a flexible printed circuit board.

A wire 205 is electrically connected to the contact pad 207 of the substrate 209 and the contact pad 208 of the chip 206, which may be performed by a wire bonding process.

The lens holder (including an upper portion 203a and a lower portion 203b) is adhered on the substrate 209 to complete the module structure 200 of the present invention. The lens holder may be a plastic piece or an actuator. Moreover, the upper portion and the lower portion of the lens holder may be integrated into an integral component. An adhesion layer 204a is formed on the lower portion 203b of the lens holder, and the transparent plate 202 is adhered on the lower portion 203a of the lens holder via the adhesion layer 204a. The transparent 202 is, for example a glass substrate or the substrate made of a transparent material. The transparent plate 202 is located above the lower portion 203b of the lens holder, for substantially aligning to the sensing area 206a. The lower portion 203b of the lens holder has a through hole structure formed therein such that the transparent plate 202 covers the through hole structure, and thereby the propagating light passing through the transparent plate 202 and directly reaching to the sensing area 206a. The transparent plate 202 covers the through hole structure of the lower portion 203b of the lens holder such that an enclosed space is created between the transparent plate 202 and the sensing area 206a, to reduce particles contamination for enhancing yield of the module structure. Size of the transparent plate 202 may be the same or larger than area of the sensing area 206a.

The transparent plate (glass substrate) 202 may be round or square type. Transparent plate (glass substrate) 202 may be optionally coated infrared coating for filtering, such as infrared filter for filtering to a certain band of frequency by passing through the lens 201. In an example, the transparent plate 202 may be adhered to the lower portion 203b of the lens holder via an adhesion layer.

The lens 201 is fixed to the upper portion 203a of the lens holder for supporting the lens 201. Moreover, the lens holder may be fixed to the substrate 209 for supporting the lens 201. The lens 201 may be optionally disposed above the lens holder. The module structure 200 of this embodiment, the transparent plate 202 may be optionally disposed within the lens holder, and between the lens 201 and the chip 206. In other words, the lens 201 is substantially aligning to the transparent plate 202 and the chip 206, and thereby the propagating light directly reaching to the sensing area 206a.

The substrate 209 is adhered to the substrate 211 via a conductive layer 210a. Trace of the substrate 209 may be electrically connected to trace of the substrate 211 via the conductive layer 210a. In one embodiment, material of the conductive layer 210a includes a conductive paste or a conductive film, which may be formed as a pattern paste on the substrate by employing a printing or coating process. The conductive layer 210a may be optically coated on the substrate 211. In one embodiment, the substrate 209 has a through hole structure formed therein for receiving or accommodating the chip 206 disposed into the through hole structure. The through hole structure passes through the top surface and the bottom surface of the substrate 209. The through hole structure is generally located at the middle of the substrate 209. Size of the substrate 209 is larger than that of the chip 206. In this embodiment, based-on the substrate 209 with the through hole structure formed therein, it equivalent to open a window area at the substrate 209. Moreover, a contact pad 207 is formed on the substrate 209. The chip 206 is directly adhered on (to) the substrate 211 via the adhesion layer 210. The adhesion layer 210 and the conductive layer 210a may be formed by using the same or different material, connected or not connected to each other. The adhesive layer 210 may be made by using a single process/material or a variety of process/materials. There is no overlapping area between the substrate 209 and the chip 206, and therefore the height of the overall module structure becomes smaller.

Size of the substrate 211 is larger than that of the substrate 209 such that the substrate 211 can extend to outside of the substrate 209 when the two substrates are combined by adhering. It should be noted that the lens holder 203, the transparent plate 202, the substrate 209, a portion of the substrate 211 and the image sensor chip 206 may be integrated into a cubic module structure. Based-on the substrate 211 extending to outside of the cubic module structure, electrical signals of the module structure 200 can be transmitted to other components outside of the cubic module structure via the trace of the substrate 211.

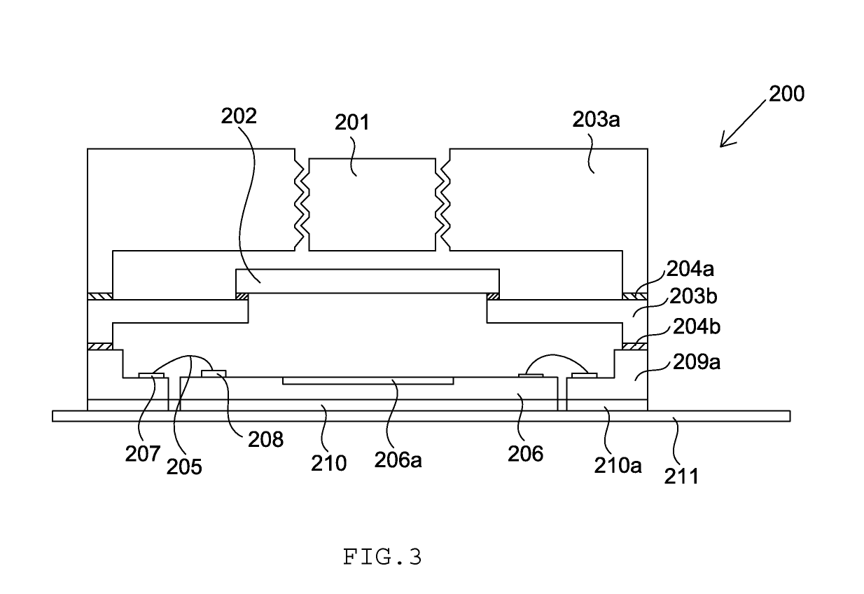

As shown in FIG. 3, it shows a sectional view of a window type camera module structure according to another embodiment of the present invention. In this embodiment, the top surface of the substrate 209 contains two regions with different step height, wherein the contact pad 207 is formed on the top surface of relative low region such that the height of the contact pad 207 is substantially equal to that of the contact pad 208 of the chip 206; wherein the adhesion layer 204b is formed on the top surface of relative high region such that the lower portion 203b of the lens holder is adhered on (to) such top surface region. Other configuration of the module structure of this embodiment is similar with that of the FIG. 2, and therefore the detailed description is omitted.

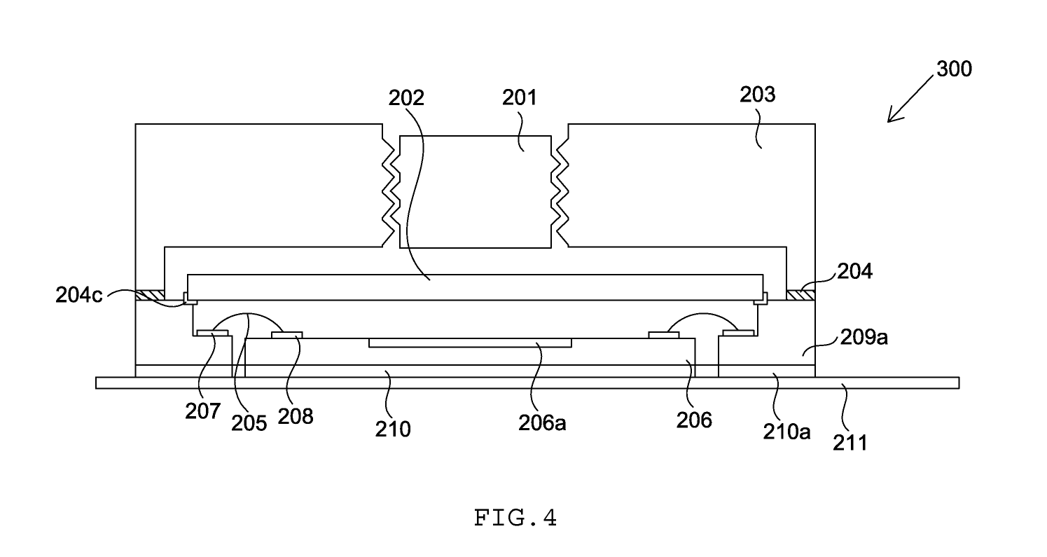

As shown in FIG. 4, it shows a sectional view of a window type camera module structure according to yet another embodiment of the present invention. Similarly, in this embodiment, the top surface of the substrate 209 contains two regions with different step height, wherein the contact pad 207 is formed on the top surface of relative low region; wherein the adhesion layer 204 is formed on the top surface of relative high region such that the periphery region of the lens holder 203 is adhered on (to) such top surface region of the substrate 209a. Moreover, the transparent plate is directly adhered to (on) the top surface of relative high region of the substrate 209a via an adhesion layer 204c. In other words, the transparent plate 202 is disposed within the lens holder 203 but not formed on the lens holder 203 (as above-mentioned embodiment). Other configuration of the module structure of this embodiment is similar with that of the FIG. 3, and therefore the detailed description is omitted.

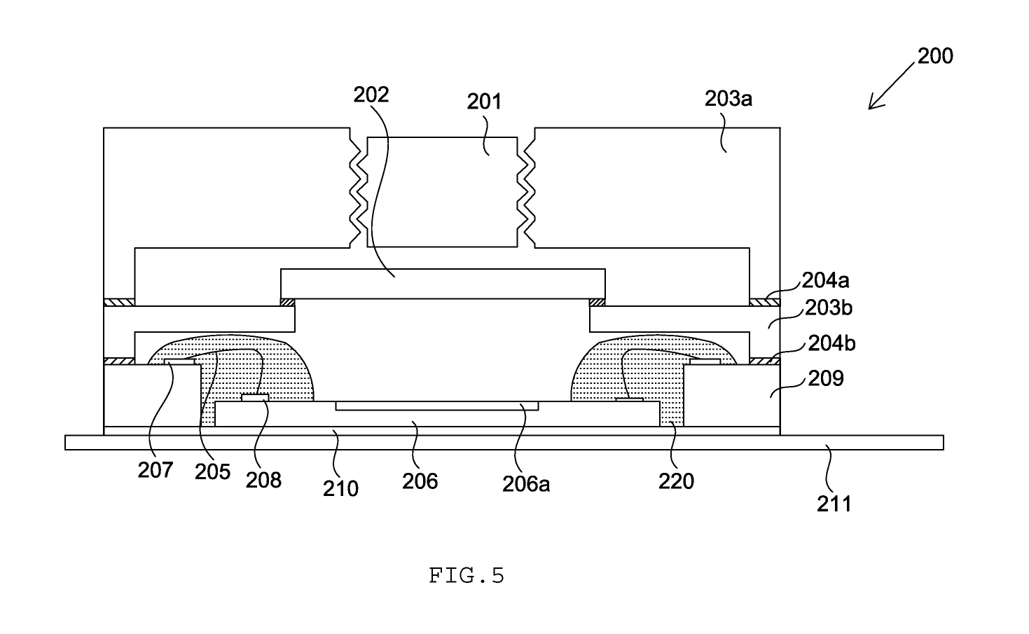

As shown in FIG. 5, it shows a sectional view of a window type camera module structure according to a further embodiment of the present invention. In this embodiment, the module structure is similar with that of the FIG. 2. The module structure 200 of this embodiment further comprises a passivation layer 220 formed on the chip 206 and the substrate 209 for fully-covering, partially-covering or non-covering over the wire 205, and filled into a gap between the chip 206 and the substrate 209 and exposing the sensing area 206a. Material of the passivation layer 220 is for example glue.

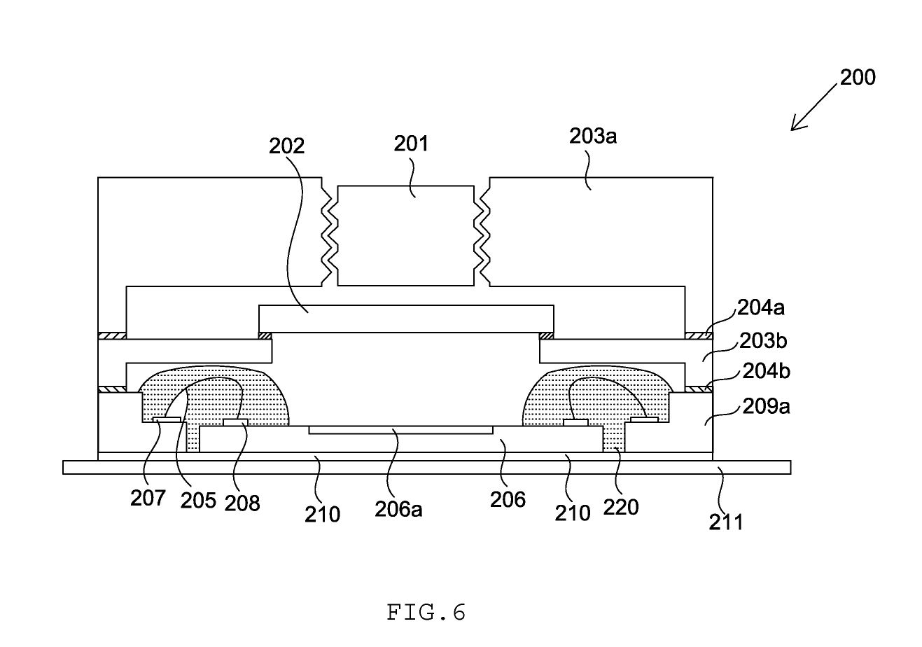

As shown in FIG. 6, it shows a sectional view of a window type camera module structure according to an embodiment of the present invention. In this embodiment, the module structure is similar with that of the FIG. 5, and therefore the detailed description is omitted. In this embodiment, the top surface of the substrate 209a includes two regions with different step height.

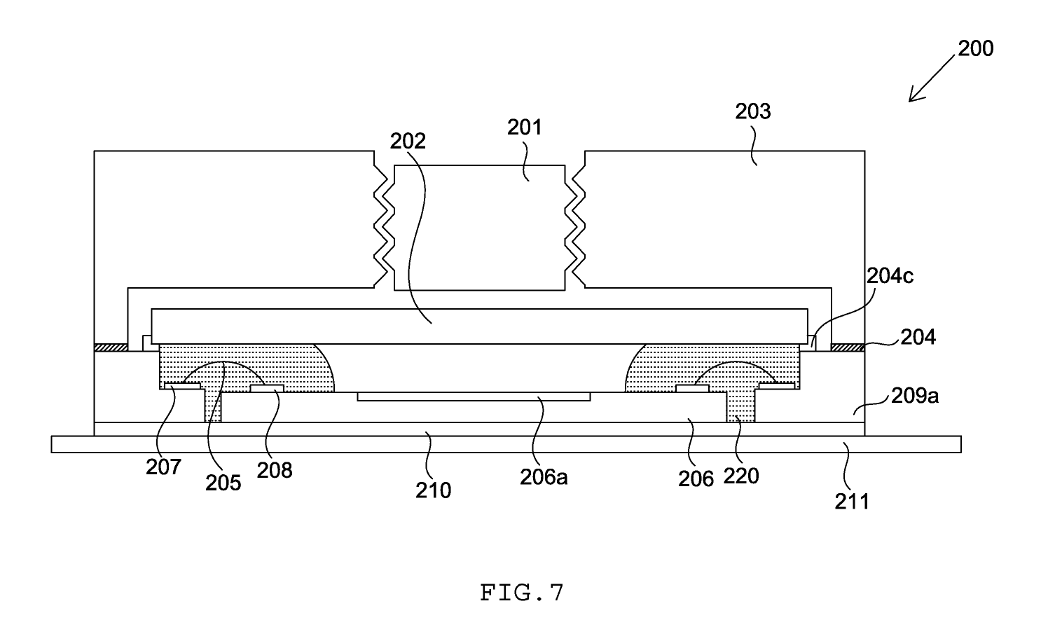

As shown in FIG. 7, it shows a sectional view of a window type camera module structure according to yet another embodiment of the present invention. Similarly, in this embodiment, the top surface of the substrate 209a includes two regions with different step height, wherein the contact pad 207 is formed on the top surface of relative low region; wherein the adhesion layer 204 is formed on the top surface of relative high region such that the periphery region of the lens holder 203 is adhered on (to) such top surface region of the substrate 209a. Moreover, the transparent plate 202 is directly adhered to (on) the top surface of relative high region of the substrate 209a. Similarly, the transparent plate 202 is disposed within the lens holder 203 but not formed on the lens holder 203 (as above-mentioned embodiment). Other configuration of the module structure of this embodiment is similar with that of the FIG. 6, and therefore the detailed description is omitted.

In one embodiment of the present invention, the substrate 209 is a printed circuit board. Besides, the substrate 209 may be an organic substrate with a pre-determined through hole, and which material includes, for example epoxy type FR5 or FR4, or BT (Bismaleimide Triazine). Moreover, glass, ceramic and silicon may be as material of the substrate 209.

The advantages of the present invention comprises smaller height of the module structure, using current wire bonding process (electrical connect method) which is easy and cheap, good thermal performance and easy to manufacture multiple chip packaging.

The foregoing descriptions are preferred embodiments of the present invention. As is understood by a person skilled in the art, the aforementioned preferred embodiments of the present invention are illustrative of the present invention rather than limiting the present invention. The present invention is intended to cover various modifications and similar arrangements included within the spirit and scope of the appended claims, the scope of which should be accorded the broadest interpretation so as to encompass all such modifications and similar structures.

What is claimed is:

1. A window type camera module structure, comprising:
a first substrate;
a chip configured on said first substrate, with a first contact pad and a sensing area;
a second substrate disposed on said first substrate, with a through hole structure and a second contact pad, wherein said chip is disposed within said through hole structure, and wherein said first contact pad is electrically connected to said second contact pad via a wire; and
a lens holder disposed on said second substrate, and a lens located on said lens holder, substantially aligning to said sensing area.

2. The module structure of claim 1, wherein said first substrate is adhered to said second substrate via a conductive layer.

3. The module structure of claim 1, further comprising a passivation layer formed on said first substrate, said chip and said second substrate, wherein said passivation layer is fully-covering, partially-covering or non-covering over said wire.

4. The module structure of claim 1, wherein said first substrate is a printed circuit board or a flexible printed circuit board, and said second substrate is a printed circuit board, and material of said second substrate comprises epoxy type FR5 or FR4, BT (Bismaleimide Triazine), glass, silicon or ceramic, wherein said printed circuit board and said flexible printed circuit board has its trace formed thereon, respectively.

5. The module structure of claim 4, wherein said printed circuit board or said flexible printed circuit board has its trace formed thereon, respectively.

6. The module structure of claim 1, wherein a top surface of said second substrate includes two regions with different step height, wherein said second contact pad is formed on a top surface of relative low region.

7. The module structure of claim 6, further comprising a passivation layer formed on said first substrate, said chip and said second substrate, wherein said passivation layer is fully-covering, partially-covering or non-covering over said wire.

8. The module structure of claim 6, further comprising a transparent material formed on a top surface of relative high region.

9. The module structure of claim 8, further comprising a passivation layer formed on said first substrate, said chip and said second substrate, wherein said passivation layer is fully-covering, partially-covering or non-covering over said wire.

10. The module structure of claim 1, further comprising a transparent material disposed said lens holder or said second substrate, wherein said lens holder is substantially aligning to said transparent material and said sensing area.

11. The module structure of claim 10, wherein said first substrate is adhered to said second substrate via a conductive layer.

12. The module structure of claim 10, further comprising a passivation layer formed on said first substrate, said chip and said second substrate, wherein said passivation layer is fully-covering, partially-covering or non-covering over said wire.

13. The module structure of claim 10, wherein said first substrate is a printed circuit board or a flexible printed circuit board, and said second substrate is a printed circuit board, and material of said second substrate comprises epoxy type FR5 or FR4, BT (Bismaleimide Triazine), glass, silicon or ceramic.

14. The module structure of claim 13, wherein said printed circuit board or said flexible printed circuit board has its trace formed thereon, respectively.

15. The module structure of claim 10, wherein a top surface of said second substrate includes two regions with different step height, wherein said second contact pad is formed on a top surface of relative low region.

16. The module structure of claim 15, wherein said transparent material is formed on a top surface of relative high region.

17. The module structure of claim 15, further comprising a passivation layer formed on said first substrate, said chip and said second substrate, wherein said passivation layer is fully-covering, partially-covering or non-covering over said wire.
